(19) United States
(12) Patent Application Publication
(10) Pub. No.: US 2007/0159080 A1
(43) Pub. Date: Jul. 12, 2007

(54) Transparent-cathode for top-emission organic light-emitting diodes

(75) Inventors: Sijin Han, North York (CA); Xiadong Feng, Toronto (CA); Zhenghong Lu, Toronto (CA); Richard P. Wood, Waterford (CA); David J. Johnson, Toronto (CA)

Correspondence Address: FAY SHARPE LLP, 1100 SUPERIOR AVENUE, SEVENTH FLOOR, CLEVELAND, OH, 44114, US

(73) Assignee: Luxell Technologies, Inc., Ontario (CA)

(21) Appl. No.: 10/535,893

(22) PCT Filed: Nov. 21, 2003
(86) PCT No.: PCT/CA03/01813

§ 371 Date: May 30, 2006

(30) Foreign Application Priority Data
Nov. 22, 2002 (CA) 2,412,379

(51) Int. Cl. H01J 9/24; H01J 1/62

(52) U.S. Cl. 313/505; 313/504; 445/24

(57) ABSTRACT

A new transparent-charge-injection-layer consisting of LiF/Al/Al-doped-SiO has been developed as (i) a cathode for top emitting organic light-emitting diodes (TOLEDs) and as (ii) a buffer layer against damages induced by energetic ions generated during deposition of other functional thin films by sputtering, or plasma-enhanced chemical vapor deposition. A luminance of 1900 cd/m² and a current efficiency of 4 cd/A have been achieved in a simple testing device structure of ITO/TPD (60 nm)/Alq₃ (40 nm)/LiF (0.5 nm)Al (3 nm)/Al-doped-SiO (30 nm). A thickness of 30 nm of Al-doped SiO is also found to protect organic layers from ITO sputtering damage.

### FIELD OF THE INVENTION

This invention relates in general to organic light emitting diodes (OLEDs), and more particularly with a top-emitting OLED with transparent cathode and method of manufacture thereof.

### BACKGROUND OF THE INVENTION

Top-emitting organic light-emitting diodes (TOLEDs), unlike conventional ones that emit light through a transparent bottom electrode (ITO) and glass substrate, are becoming increasingly important for the integration of OLED devices with electrical drivers. Top emission is desirable for active-matrix OLED displays because all circuitry can be placed at the bottom of the device without any interference from components, such as wiring and transistors. TOLEDs are eminently suitable for making microdisplays because of the high level of integration of necessary driver circuits with the matrix structure of OLEDs on a silicon chip. Therefore, design and fabrication of a top transparent cathode is an enabling technology for high-end OLED displays.

Intensive studies on conventional OLEDs have been well documented. However, there is limited information on the fabrication of TOLED devices. The use of radio frequency (RF) sputtered ITO as a top transparent electrode with a buffer layer such as MgAg, phthalocyanine (CuPc) or 3,4,9,1O-perlyenetetracarboxylic dianhydride (PTCDA) films have been reported. See, for example, the following references: G. Gu, V. Bulovic, P. B. Burrows, S. R. Forrest and M. E. Thompson, Appl. Phys, Left. 68,2606 (1996); W. E. Howard and 0. F. Prache, IBM J. Res. & Dcv. 45,115 (2001); V. Bulovic, P. Tian, P. E. Burrows, M. R. Gokhale, S. R. Forrest and M. E. Thompson, Appi. Phys. Lett. 70, 2954 (1997); L. S. Hung, C. W. Tang, Appl. Phys. Lett. 74, 3209 (1999); and G. Parthasarathy, P. E. Burrows, V. Khalfin, V. G. Kozlov, and S. R. Forrest, Appl. Phys. Lett. 72,2138 (1998). However, damage to the underlying organic layer induced by energetic ion sputtering, as discussed in greater detail below, is a major problem affecting device yield. It is thus believed that the only possible cathode deposition method has to be based on thermal evaporation, as set forth in: L. S. Hung, C. W. Tang, M. G. Mason, P. Raychaudhuri, and J. Madathil, Appl. Phys. Left. 78, 54 (2001). However, it is not known from the prior art how to fabricate a TOLED cathode based solely on thermal evaporation.

### SUMMARY OF THE INVENTION

It is therefore an object of the present invention to provide a novel transparent-cathode for top emission OLEDs that obviates or mitigates at least one of the above-identified disadvantages of the prior art. In an aspect of the invention, there is provided a stack structure of LiF/Al/Al-doped SiO multilayers, for use as a (a) top electrode and (b) buffer layer against radiation damage of organic layers due to RFsputter deposition of other active and passive over layers.

A new transparent-charge-injection-layer consisting of LiF/Al/Al-doped-SiO has been developed as (i) a cathode for top emitting organic light-emitting diodes (TOLEDs) and as (ii) a buffer layer against damage induced by energetic ions generated during deposition of other functional thin films by sputtering, or plasma-enhanced chemical vapor deposition. A luminance of 1900 cd/m² and a current efficiency of 4 cd/A have been achieved in a simple testing device structure of ITO/TPD (60 nm)/Alq₃ (40 nm)/LiF (0.5 nm)/Al (3 nm)/Al-doped-SiO (30 nm). A thickness of 30 nm of Al-doped SiO is also found to protect organic layers from ITO sputtering damage.

### BRIEF DESCRIPTION OF THE DRAWINGS

Preferred embodiments of the present invention will now be explained, by way of example only, with reference to the attached Figures in which:

FIG. 1 is a schematic cross-sectional diagram of a top-emitting OLED structure in accordance with an embodiment of the invention;

FIG. 2 is a graph showing Luminance (L)-current density (J)-voltage (V) of (a) OLED and (b) TOLED;

FIG. 3 is a graph showing efficiencies of OLED and TOLED; and

FIG. 4 depicts electroluminescent spectra of a TOLED according to the present invention with different thickness of ITO.

### DETAILED DESCRIPTION OF THE INVENTION

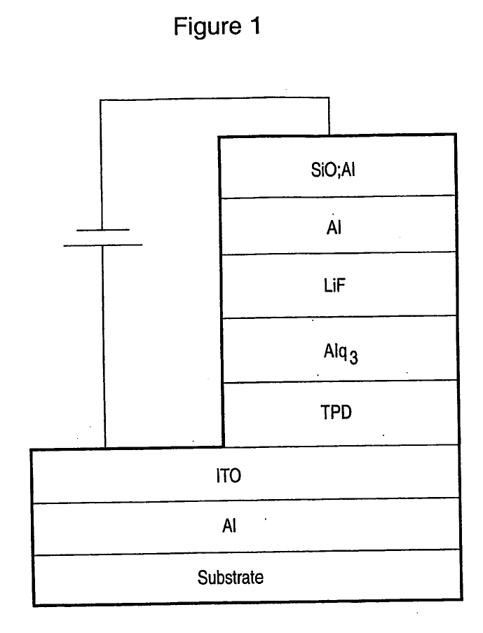

Referring now to FIG. 1, a cross-sectional diagram of a top-emitting OLED device in accordance with an embodiment of the invention is shown. Devices according to this embodiment were fabricated using a Kurt J. Lesker OLED cluster-tools for 4″×4″ substrate. The cluster-tools include a central distribution chamber, a loadlock chamber, a plasma treatment chamber, a sputtering chamber, an organic deposition chamber, and a metallization chamber. N,N′diphenyl-N,N′-bis(3-methylphenyl)-1,1′-biphenyl-4,4′-diamine (TPD) and tris-(8-hydroxyquinoline) aluminum (Alq₃) were used as a hole transport layer (HTL) and electron transport layer (ETL), respectively. Both conventional OLED and TOLED devices were fabricated on 2″×2″ substrates for the purpose of device characteristic comparisons. The device structure of the OLED is ITO/TPD/Alq₃/LiF/Al, whereas the structure of the TOLED is as shown in FIG. 1.

Fabrication was as follows: After the substrate was treated by oxygen plasma for 10 minutes in the plasma chamber, it was transferred to the sputtering chamber where ˜50 nm of ITO was deposited by RF sputtering at a power of 45 W and an argon pressure of 8.5 mTorr. The reflective al layer was then deposited, and a grid shadow mask was used to define metal/ITO anode structures to a thickness ranging from 5 nm to 500 nm. Where the anode is a thin metal film (i.e. <30 nm), light is transmitted therethrough. Suitable metals include Al, Cr, Ag, etc., or alloys of two or more elements. ITO provides good work function matching to the adjacent hole transportation layer. The thickness of ITO ranges from 1 nm to 1000 nm depending on optical cavity design, and is characterised by a sheet resistance of ITO is ˜3.00/square. TPD (60 nm), Alq₃ (40 nm), LiF (0.5 nm), and Al (3 nm) were sequentially deposited by thermal evaporation in the organic and metallization chambers. Al-doped SiO (Al:SiO) films were deposited to a thickness of approximately 30 nm through a second shadow mask by co-evaporation of Al and SiO. Additional ITO layers were sputtered onto the Al:SiO on some devices to evaluate its robustness against sputter damage. The devices were finally encapsulated with a 100 nm thick SiO film by thermal evaporation. Luminance-current-voltage (L-I-V) characteristics of the devices were measured using a HP 4140B pA meter and a Minolta LS-110 meter.

Table I summarizes the performance and yield of TOLEDs and OLEDs with various cathode structures, where the sputtering power is 8 W unless otherwise indicated. Sputtering damage may be characterised by the performance of the LEDs and the yield of pixels. The poor yields seen in rows 1 and 2 of Table I indicate that sputtering damage is a serious issue, and that CuPc films are insufficient to prevent the bombardment of ions in the organic layer during sputtering at a power of 40 W. Although the damage is somewhat reduced when the RF-power is lowered to 15 W, the few surviving TOLEDs have very low luminance. Regular OLEDs have been fabricated with Al and Al/sputtered ITO cathodes and the results are shown in the third and fourth rows of Table I. The data show that the performance of the device with the structure of Al(30 nm)/ITO as the cathode is not as good as for a cathode with Al only. Here, the RF condition was reduced to 8 W at 8.0 mTorr, which resulted in a very slow deposition rate at 0.036 Å/s. The OLED results also suggest that an inorganic buffer layer with a thickness more than 300 Å reduces the sputtering damage. All metal films of this thickness are optically opaque and can therefore greatly reduce the light output if a thick metal filn is used as a buffer layer for sputtering of ITO.

TABLE I

| Device | Cathode structures | Performance | Yield |
|---|---|---|---|
| TOLED | CuPc(7, 14, 2l nm)/LiF/ITO | Non-functional | 0% |
| | (RF power 45 W) | | |
| TOLED | CuPc(15 nm)/ITO | <50 cd/m² at 20 V | <25% |
| | (RF power 10 W) | | |
| OLED | LiF/Al (100 nm) | ˜5000 cd/m² at 6.4 V | 100% |
| OLED | LiF/Al (30 nm)/ITO | ˜5500 cd/m² at 11 V | <70% |
| TOLED | LiF/Al (3 nm)/Al:SiO (30 nm)/ | ˜1600 cd/m² at 25 V | >90% |
| | ITO | | |
| TOLED | LiF/Al (3 nm)/Al:SiO (30 nm) | ˜1590 cd/m² at 20 V | >90% |

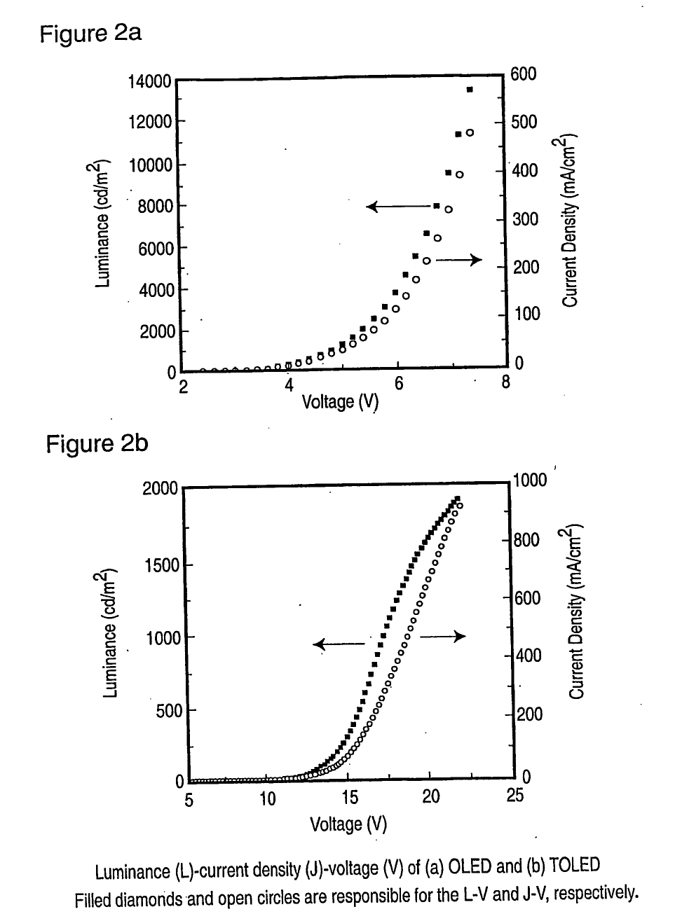

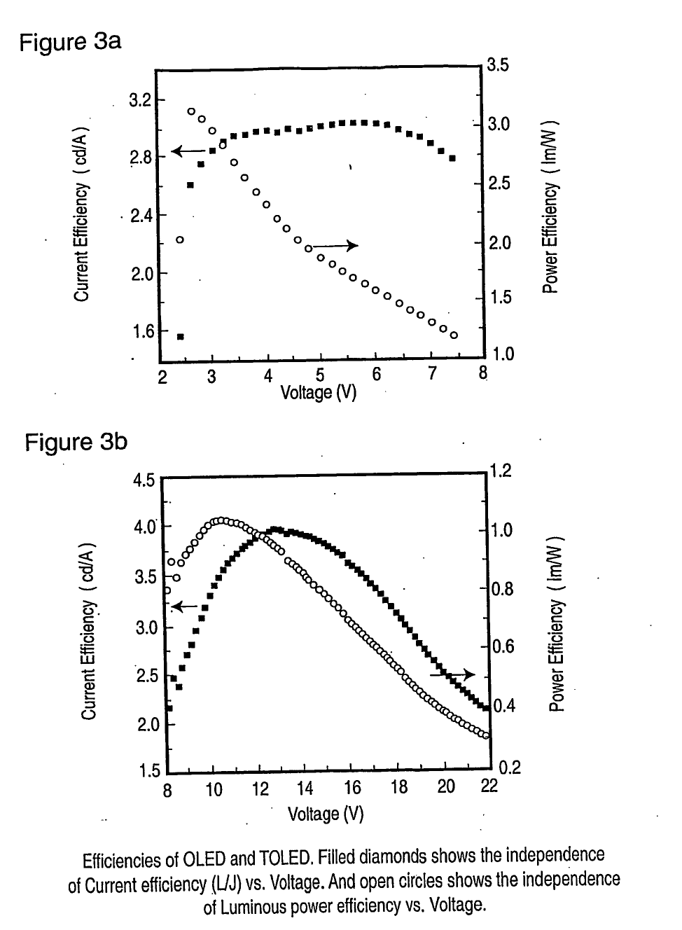

FIG. 2. shows the L-I-V curves of the fourth device (OLED) and sixth device (TOLED) of Table I. The performance of the conventional OLEDs fabricated using the organic cluster tool used in the fabrication described above, is similar to that reported in recent literature see C. F. Qiu, H. Y. Chen, Z. L. Xie, M. Wong, and H. S. Kwok, Appl. Phys. Left. 80, 3485 (2002); and W. P. Hu, K. Manabe, T. Furukawa, and M. Matsuniura, Appi. Phys. Left. 80, 2640 (2002). At 13.6 V, the luminance of TOLED reaches 100 cd/cm², which is a typical minimum requirement for video displays, and luminscence of 1900 cd/cm² may be obtained at a current density of 922 mA/cm². The current efficiency and luminous power efficiency vs voltage are shown in FIG. 3. It will be noted that current efficiency of TOLED is better than that of OLED, while the power efficiency shows a reverse trend. Several factors contribute to this difference. First, the sputtered ITO anode for TOLED has a much higher resistivity than that of the commercial ITO anode used for OLED. Second, the Al:SiO cathode for TOLED also has a much higher resistivity than that of the Al cathode used for OLED. Although the overall performance of TOLED is not as good as that of OLED, the TOLED performance data shown in FIGS. 2 and 3 is better than prior art published results, as set forth, for example in W. E. Howard et al., discussed above. The TOLEDs of the present invention were fabricated using only thermal evaporation.

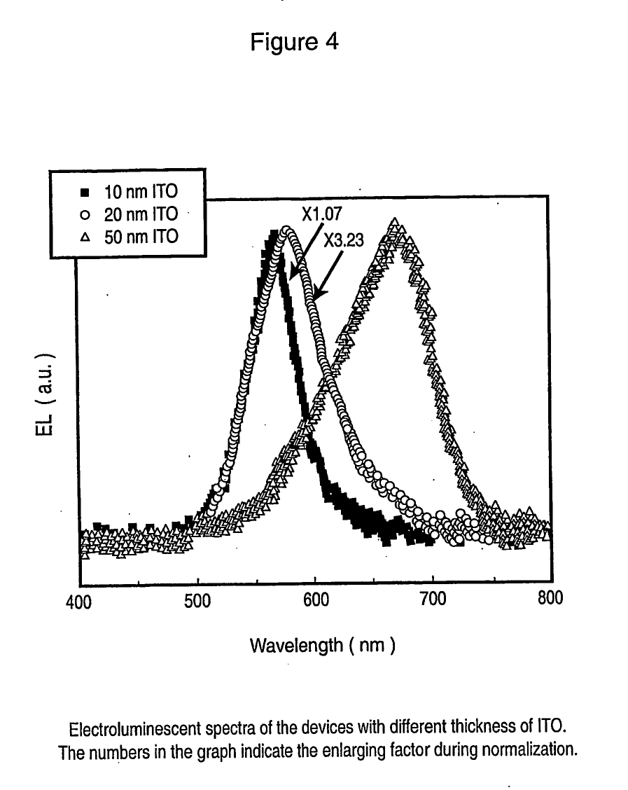

One interesting phenomena observed in the TOLED devices of the present invention is that the EL peak position or color varies significantly depending on ITO thickness. FIG. 4 shows the typical EL spectra (with peak high normalized) recorded on TOLED with ITO thickness of 10, 20 and 50 nM, respectively, as labelled. Since those devices were fabricated on the same substrate, with the organic films and top cathode deposited under identical conditions, other uncertainties in organic layer thickness variation, are excluded. It will be noted that the EL peak position shifts to longer wavelengths as the ITO layer thickness is increased. This shift may be attributed to multiple factors including optical microcavity and surface plasmons cross coupling. Researchers in the prior art have reported the detailed mechanism of microcavity effects on the optical characteristics in OLEDs (see A. Dodabalapur, L. J. Rothberg, R. H. Jordan, T. M. Miller, R. E. Slusher and J. M. Phillips, J. Appi. Phys., 80 12 (1996).; A Dodabalapur, L. J. Rothberg and T. M. Miller, Appl. Phys. Left., 652308 (1994); and V. Bulovic, V. B. Khalfin, G. Gu, P. E. Burrows, D. Z. Garbuzov and S. R. Forrest, Physical Review B. 58 3730 (1998)). Recently, Gifford et al. and Hobson et al. have investigated the role of surface plasmon loss in OLEDs (see D. K. Gifford and D. G. Hall, Appl. Phys. Left., 80 3679 (2002) and P. A. Hobson, J. A. E. Wasey, I. Sage and W. L. Barnes, IEEE J. on Selected Topics in Quantum Electronics. 8 378 (2002)). The TOLED device of the present invention gives results that are somewhat similar to Gifford's observations. The rough ITO surface of the TOLEDs according to the present invention is believed to play the same role as that of the intentionally patterned surface used in Gifford's device. A red-shi occurs when a light beam is caused to bounce off a reflective surface with energy loss to excite various surface plasmon modes. This also may explain the rather broad shifted EL spectra, whereas pure microcavity effect only predicts sharp shifted peaks.

In summary, TOLEDs on a silicon substrate have been fabricated using a new cathode consisting of a multilayer stack of LiF/Al/SiO:Al. A luminance of 1900 cd/m² at 922 mA/cm² and a current efficiency of 4 cd/A were achieved. It has been shown that the new transparent cathode is fairly robust against radiation damage, which permits deposition of other active and passive films by sputtering or other aggressive plasma processes such as ECR or PECVD. The data collected from tests of this new device indicates that the metal-doped SiO film may be used for use as a transparent electrode in TOLED:

While only specific combinations of the various features and components of the present invention have been discussed herein, it will be apparent to those of skill in the art that desired sub-sets of the disclosed features and components and/or alternative combinations and variations of these features and components can be utilized, as desired. For example, in one embodiment, the small molecule organic light emitting materials may be replaced with polymer light emitting materials. Typical polymer materials consist of PEDT as a hole injection layer and there are many types of emissive materials such as MEH-PPV, Covion yellow or Dow K2. These materials are typically spin coated or ink et deposited. In the simplest form, a single emitting polymer layer is used. All such modifications and embodiments are believed to be within the sphere and scope of the invention as defined by the claims appended hereto.

1. A top emitting OLED, comprising:
a substrate;
an anode deposited above said substrate;
light emitting hole transport and electron transport regions deposited above said anode; and
a transparent cathode deposited above said light emitting regions, wherein said transparent cathode comprises a LiF/Al/AISiO stack, and wherein said light emitting regions emit light in response to voltage being applied across said anode and cathode.

2. The top emitting OLED of claim 1, wherein said light emitting regions are layers of organic material.

3. The top emitting OLED of claim 1, wherein said layers of organic material comprise TPD functioning as a hole transport layer and Alq₃ functioning as an electron transport layer.

4. The top emitting OLED of claim 1, wherein said light emitting regions comprise polymer light emitting materials.

5. The top emitting OLED of claim 1, wherein said anode comprises stacked multiple metal/ITO films.

6. The top emitting OLED of claim 5, further including a further Al layer intermediate said substrate and said metal/ITO films.

7. In a method of fabricating an OLED, including providing a substrate; sputtering an anode above said substrate; thermally evaporating light emitting hole transport and electron transport regions onto said anode; and sputtering a cathode above said light emitting regions; the improvement comprising depositing an aluminum-doped SiO buffer layer to protect said light emitting regions from radiation damage due to said sputtering of said cathode.

8. The improvement of claim 7, wherein said substrate is treated with an oxygen plasma prior to sputtering of said anode.

9. The improvement of claim 8, wherein said anode is stacked multiple metal/ITO films RF sputtered onto said substrate at a power of approximately 45 W in an argon atmosphere at a pressure of 8.5 mTorr and patterned using a grid shadow mask.

10. The improvement of claim 9, wherein said light emitting regions are organic layers of TPD and Alq₃ sequentially deposited via thermal evaporation on said metal/ITO films.

11. The improvement of claim 9, wherein said light emitting regions comprise polymer light emitting materials deposited via thermal evaporation on said metal/ITO films.

12. The improvement of claim 10, including further sequential thermal evaporation of LiF and Al layers onto said organic layers.

13. The improvement of claim 11, including further sequential thermal evaporation of LiF and Al layers onto said polymer layers.

14. The improvement of claim 12, wherein said aluminum-doped SiO buffer layer is deposited through a further shadow mask by co-evaporation of Al and SiO.

15. The improvement of claim 13, wherein said aluminum-doped SiO buffer layer is deposited through a further shadow mask by co-evaporation of Al and SiO.

16. The improvement claim 7, wherein said buffer layer is deposited to a thickness of at least 300 Å.

17. The improvement of claim 8, wherein said buffer layer is deposited to a thickness of at least 300 Å.

18. The improvement of claim 9, wherein said buffer layer is deposited to a thickness of at least 300 Å.

19. The improvement of claim 14, wherein said buffer layer is deposited to a thickness of at least 300 Å.

20. The improvement of claim 15, wherein said buffer layer is deposited to a thickness of at least 300 Å.
